(19) United States
(12) Patent Application Publication
(10) Pub. No.: US 2019/0090384 A1
(43) Pub. Date: Mar. 21, 2019

(54) PIPELESS LIQUID-COOLED HEAT DISSIPATION SYSTEM

(71) Applicant: Apaltek Co., LTD, ShenZhen (CN)

(72) Inventor: QINENG XIAO, DongGuan (CN)

(73) Assignee: Apaltek Co., LTD, ShenZhen (CN)

(21) Appl. No.: 16/183,697

(22) Filed: Nov. 7, 2018

(30) Foreign Application Priority Data
Jun. 1, 2018 (CN) 2018105572522

(51) Int. Cl. H05K 7/20; F28F 9/26

(52) U.S. Cl. CPC H05K 7/20263; F28F 2275/06; H05K 7/20272; F28F 9/268

(57) ABSTRACT

A pipeless liquid-cooled heat dissipation system includes a heat dissipation device, a pumping device, a water reservoir, and a heat absorption device, which are integratedly combined and interconnected without a pipe. An interior of the water reservoir is partitioned into at least two space regions to control a flow direction of the liquid. A hole-slot structure is arranged on the water reservoir. The pumping device is installed in the hole-slot structure and interconnected with the water reservoir. The heat absorption device is further configured on the water reservoir and interconnected with the water reservoir. The water reservoir and the heat dissipation device are integrally formed by welding and are interconnected with each other.

### CROSS REFERENCE TO RELATED APPLICATIONS

This application is based upon and claims priority to Chinese Patent Application No. 201810557252.2, filed on Jun. 1, 2018, the entire contents of which are incorporated herein by reference.

### TECHNICAL FIELD

The present invention relates to a heat dissipation system, particularly to a pipeless liquid-cooled heat dissipation system for electronic equipment.

### BACKGROUND

Nowadays, the electronic device such as a CPU, a graphics card, a chip of electronic apparatus, etc. are usually cooled by a liquid-cooled radiator, which is mainly composed of three main parts, namely, a heat absorption device, a power system, and a heat dissipation device. The three parts are connected to form a closed liquid circulation loop. The heat-absorption device is connected to the heat-emitting body. The power system provides power for the liquid to circulate in the loop. This design includes the following defects. The three parts are assembled and fixed by an external connection of the connecting pipes, so there are a large number of joints. As a result, there is a high risk of liquid leakage, and the device will occupy a large space. Chinese Patent Application CN1921743A discloses an integrated liquid cooling heat abstractor, due to the complicated overall design and monotonous design style, the installation operation of the heat abstractor is inconvenient, and the heat abstractor has poor installation flexibility, which greatly limits its application.

### SUMMARY

The technical problem to be solved by the present invention is, specific to the drawbacks of the liquid-cooled system in the prior art, to provide a pipeless liquid-cooled heat dissipation system.

The technical solution adopted by the present invention to solve the technical problem is as follows. A pipeless liquid-cooled heat dissipation system includes a heat dissipation device, a pumping device, a water reservoir, and a heat absorption device. The pumping device, heat absorption device, heat dissipation device, and water reservoir are integrated and interconnected without a pipe. An interior of the water reservoir is partitioned into at least two space regions to control the flow direction of the liquid. A hole-slot structure is arranged on the water reservoir, and the pumping device is installed in the hole-slot structure and interconnected with the water reservoir. The heat absorption device is further integratedly configured on the water reservoir and interconnected to the water reservoir. The water reservoir and the heat dissipation device are integratedly formed by welding and are interconnected with each other.

Preferably, the manner of the integrated formation by welding includes directly welding the water reservoir and the heat dissipation device by special equipment after butting the interfaces of the raw material of the water reservoir and the heat dissipation device or welding the water reservoir and the heat dissipation device through a third-party welding flux.

Preferably, the water reservoir includes two space regions A and B, and the two space regions A, B are connected by the heat dissipation device. The heat absorption device includes a water inflow region and a water outflow region. The pumping device directly pumps the cooling liquid from the space of region A to the water inflow region of the heat absorption device, and then the cooling liquid is transferred from the space of region B through the water outflow region of the heat absorption device.

Preferably, the water reservoir includes three space regions A, B and C. The dissipation device is interconnected with region A. The pumping device pumps the cooling liquid from region A to region B, the cooling liquid in the region B is transferred to the space of region C through the heat absorption device. The region A and the region C are connected to a water inflow channel and a water outflow channel of the heat dissipation device, respectively.

Preferably, the heat dissipation devices are configured at the two sides of the water reservoir, respectively. The water reservoir is partitioned into four space regions A, B, C and D. The pumping device pumps the cooling liquid to region B from region A. The region A and region D, and the region B and region C are connected by the two heat dissipation devices, respectively. The cooling liquid in region C is transferred to region D through the heat absorption device.

Preferably, the water reservoir has a thin flat shape, the heat dissipation device is flat large U-shaped pipelines, and the heat dissipation device is provided with a turbo fan.

Preferably, the pumping device includes a pump housing, an impeller, a motor, and a pump cover component, and the pumping device is locked and sealed with the water reservoir through a sealing device.

Preferably, the heat absorption device is a metal piece with high heat conductivity.

The heat absorption device is locked and sealed on the water reservoir through the sealing device or integrated welding, or the interior of the water reservoir is provided with the heat absorption device, or the original internal structure of the water reservoir forms the heat absorption device.

Preferably, the sealing device is an elastic gum seal ring, an elastic gum seal pad, or a glue-like filling and sealing material, etc.

Preferably, the water reservoir may be provided and interconnected with N pumping devices, N≥2, N heat absorption devices, N≥2, and N heat dissipation devices, N≥2.

The pipeless liquid-cooled heat dissipation system provided by the present invention integratedly combines and interconnects the pumping device, the heat absorption device, the heat dissipation device, and the water reservoir together in a pipeless manner. The interior of the water reservoir is partitioned into at least two space regions to control the flow direction of the liquid. The water reservoir is provided with a hole-slot structure, the pumping device is installed in the hole-slot structure and is interconnected with the water reservoir. The heat absorption device is further configured on the water reservoir and interconnected with the water reservoir. The water reservoir and the heat dissipation device are integratedly formed and interconnected by welding. The present invention realizes a maximum integrated design of the water reservoir, heat dissipation device, pumping device, and heat absorption device, greatly saves the space occupied by the liquid-cooled heat dissipation system, increases the installation flexibility and facilitates the installation and use.

### BRIEF DESCRIPTION OF THE DRAWINGS

In order to clearly illustrate the technical solutions of the embodiments of the present invention, the drawings needed for the descriptions of the embodiments are briefly introduced below. Obviously, the drawings described below are merely some embodiments of the present invention, for those of ordinary skill in the art, other drawings can be derived according to these drawings without creative efforts. In the drawings:

FIG. 1 is an overall structural schematic diagram of a first embodiment of the liquid-cooled heat dissipation system of the present invention;

FIG. 2 shows an exploded view of FIG. 1 and a schematic diagram of structural partitions of the water reservoir;

FIG. 3 is an overall structural schematic diagram showing the water reservoir in FIG. 1;

FIG. 4a, FIG. 4b and FIG. 4c are schematic diagrams showing three manners of welding the water reservoir with the heat dissipation device according to the first embodiment of the liquid-cooled heat dissipation system of the present invention;

FIG. 5 is a flow schematic diagram showing the liquid circulation of the liquid-cooled system of the present invention;

FIG. 6a is a schematic diagram showing that the heat absorption device and the water reservoir of the liquid-cooled heat dissipation system of the present invention are integratedly welded;

FIG. 6b is a schematic diagram showing that the heat absorption device is fixedly connected inside the water reservoir in the liquid-cooled heat dissipation system of the present invention;

FIG. 6c is a schematic diagram showing that the heat absorption device is the original internal structure of the water reservoir in the liquid-cooled heat dissipation system of the present invention;

FIG. 7 is a structural schematic diagram of a second embodiment of the liquid-cooled heat dissipation system of the present invention, showing that the heat dissipation system is welded on a side of the water reservoir;

FIG. 8a and FIG. 8b are structural schematic diagrams showing another connection structure of the third embodiment of the liquid-cooled heat dissipation system of FIG. 7;

FIG. 9a and FIG. 9b are structural schematic diagrams of a fourth embodiment of the liquid-cooled heat dissipation system of the present invention;

FIG. 10a is a structural schematic diagram showing that two water reservoirs and four heat absorption devices are respectively configured at two sides of the heat dissipation device of the liquid-cooled system of the present invention;

FIG. 10b is a structural schematic diagram of FIG. 10a viewing from another angle;

FIG. 10c is a schematic diagram showing the liquid circulation process inside the structure of 10a;

FIG. 11a is a structural schematic diagram showing a design that the heat dissipation device of the liquid-cooled heat dissipation system and the pumping device of the water reservoir are integratedly formed with an angle in the present invention;

FIG. 11b is a structural schematic diagram of FIG. 11a viewing from the bottom;

FIG. 11c is a front view of FIG. 11a;

FIG. 11d is a partially enlarged view of FIG. 11-c which shows the liquid circulation process;

FIG. 12a is a schematic diagram showing an integrated design of multiple heat dissipation devices and the heat absorption device of the liquid-cooled heat dissipation system of the present invention;

FIG. 12b is a structural schematic diagram of FIG. 12a viewing from another angle;

FIG. 12c is a front view of FIG. 12a;

FIG. 12d is a side view of FIG. 12a;

FIG. 12e is a partially enlarged view of FIG. 12d which shows the liquid circulation process;

FIG. 13a is a structural schematic diagram showing an ultra-thin design of the liquid-cooled heat dissipation system of the present invention;

FIG. 13b is a schematic diagram showing the reverse side of FIG. 13a;

FIG. 13c is a sectional view of FIG. 13a;

FIG. 13d is a schematic diagram showing the internal liquid circulation process of FIG. 13a;

FIG. 14a is a schematic diagram showing an annular structure design of the liquid-cooled heat dissipation system of the present invention;

FIG. 14b is a schematic diagram showing the reverse side of FIG. 14a; and

FIG. 14c is a partially enlarged view of A-A sectional view of FIG. 14a, showing the internal liquid circulation process.

### DETAILED DESCRIPTION OF THE EMBODIMENTS

In order to clarify the objectives, technical solutions and advantages of the present invention, the embodiments will be described hereinafter with reference to the corresponding drawings, and these drawings constitute a part of the embodiments. Various embodiments that may be implemented to realize the present invention are described. It should be understood that the present invention may further include other embodiments, or modifications of the listed embodiments in structure and function without departing from the scope and essence of the present invention.

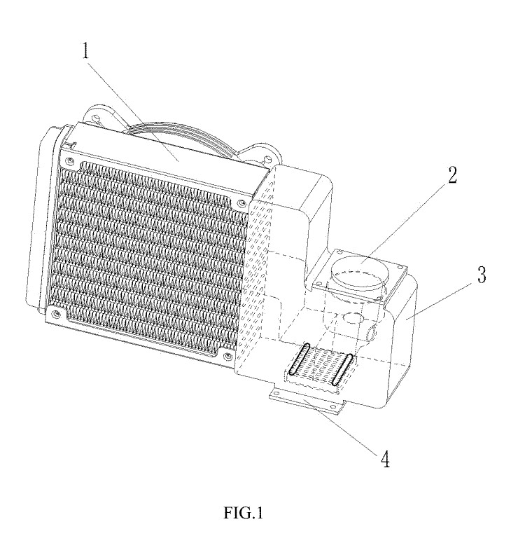

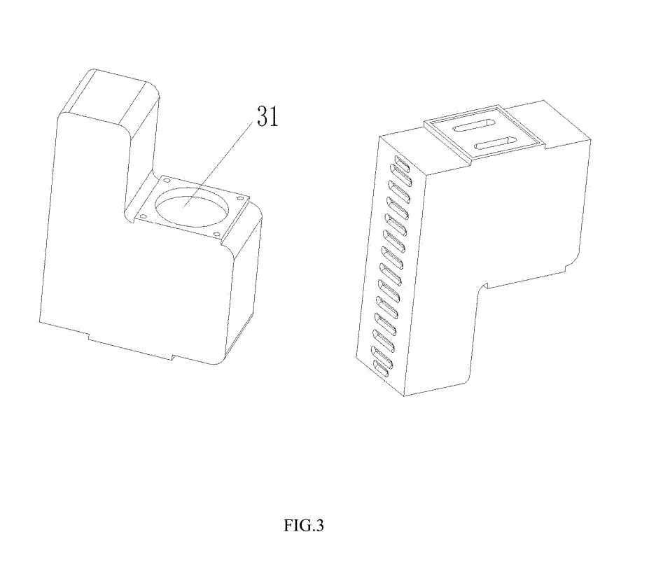

Referring to FIG. 1 to FIG. 3, the pipeless liquid-cooled heat dissipation system of the present invention includes heat dissipation device 1, pumping device 2, water reservoir 3, and heat absorption device 4. The pumping device 2, heat absorption device 4, heat dissipation device 1, and water reservoir 3 are integratedly combined and interconnected without a pipe, namely, the connecting pipes therebetween are saved, thus, avoiding the liquid leakage at the joints of the pipes, reducing the size of the entire system, simplifying the structure of the system, and facilitating the installation of the system. The interior of the water reservoir 3 is partitioned into at least two space regions to control the flow direction of the liquid, and thus, the interior of the water reservoir 3 is partitioned into several regions, such as a water inflow region, a water outflow region etc. Accordingly, the normal liquid circulation of heat absorption and dissipation can be achieved. The water reservoir 3 is further provided with the heat absorption device 4, and the heat absorption device 4 is interconnected with the water reservoir 3. The heat absorption device 4 may be locked and fixed in the hole-slot structure of the water reservoir 3 or welded on the water reservoir 3 to form an integrated structure. The heat absorption device 4 may be fixed inside the water reservoir 3, namely, the water reservoir 3 formed with a heat absorption region. Also, the heat absorption device is a metal piece with high heat conductivity which is integratedly welded inside the water reservoir and attached on the inner surface of the water reservoir. The heat absorption device may also be the original structure of water reservoir 3, namely, the heat absorption device is integratedly formed with the water reservoir 3. In the case that the heat absorption device 4 is configured inside the water reservoir 3, when cooling the heat-emitting devices, the outer surface of the position of the water reservoir 3 corresponding to the heat absorption device 4 is directly attached with the heat emitting device to conduct heat. Referring to FIG. 3, the water reservoir 3 and the heat dissipation device 1 are integratedly welded and interconnected, a circular hole-slot structure 31 on the water reservoir 3 is configured for installing the pumping device 2, and the pumping device 2 is interconnected with the water reservoir 3. In this way, the pumping device, the heat dissipation device, and the heat absorption device are all integratedly interconnected with the water reservoir, and the interior of the water reservoir is partitioned into different regions to control the flow direction of the liquid.

Through the above structure, the pipeless liquid-cooled heat dissipation system of the present invention maximumly reduces the occupation space and the risk of liquid leakage. Also, the various parts are compact in structure, thereby, realizing the minimum volume of the system, and facilitating the installation and use.

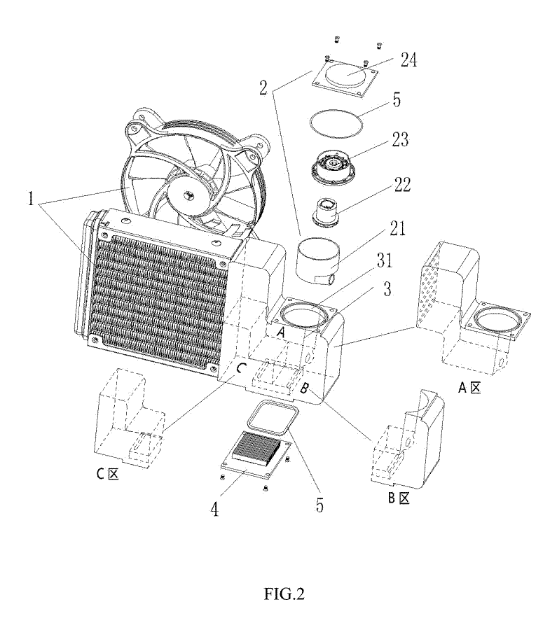

Specifically, referring to FIG. 2, the pumping device 2 includes pump housing 21, impeller 22, motor 23, and pump cover component 24. The pumping device 2 is locked and sealed with the water reservoir 3 through the sealing device 5. It should be noted that the inner wall of the hole-slot structure may be used as the pumping house of the pumping device or the entire pumping device, thus, saving the cost of the pumping device.

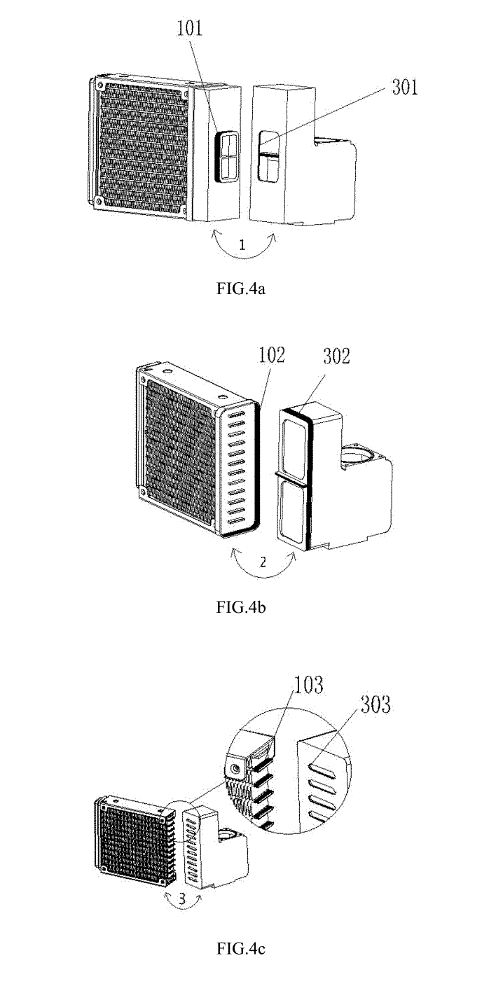

Further, the manner of integratedly welding the water reservoir 3 and the heat dissipation device 1 includes directly welding the water reservoir 3 and the heat dissipation device 1 by special equipment after butting the interfaces of the raw material of the water reservoir 3 and the heat dissipation device 1, or welding the water reservoir 3 and the heat dissipation device 1 through a third-party welding flux. Referring to the first manner shown in FIG. 4, the water reservoir 3 is provided with an opening 301, the corresponding part of the heat dissipation device 1 has a protrusion 101, the opening 301 matches with the protrusion 101. The water reservoir and the heat dissipation device can be integratedly formed by welding the contact surfaces therebetween. Referring to the second manner shown in FIG. 4a-FIG. 4c, an outer peripheral surface 302 of the edge of water reservoir 3 is integratedly welded with an inner peripheral surface 102 of the corresponding edge of heat dissipation device 1 to integrate the water reservoir and the heat dissipation device. Referring to the third manner shown in FIG. 4, the heat dissipation device 1 is provided with cooling pipes 103, the water reservoir 3 is correspondingly provided with holes 303, and the cooling pipes 103 are inserted into the holes 303 and welded.

Further, the heat absorption device 4 is a metal piece with high heat conductivity. The heat absorption device 4 is locked and sealed on the water reservoir 3 through the sealing device 5 or integratedly welded.

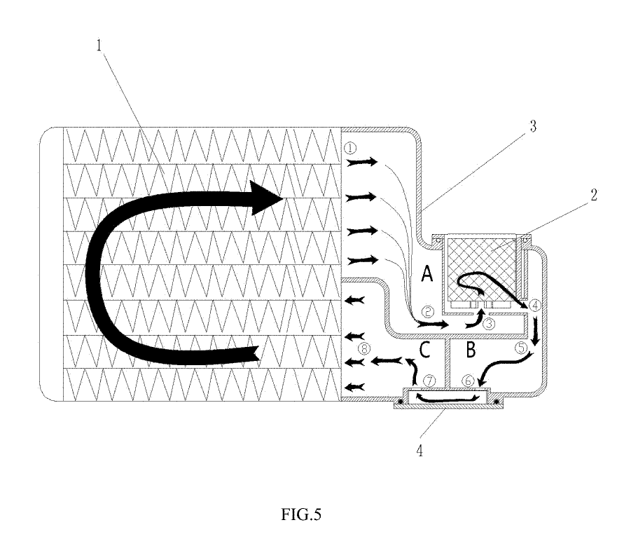

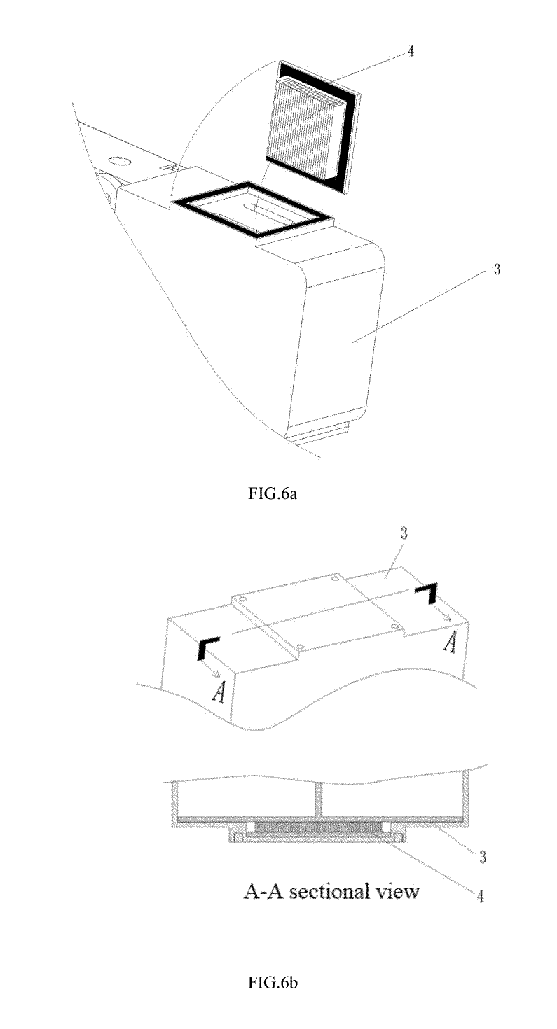

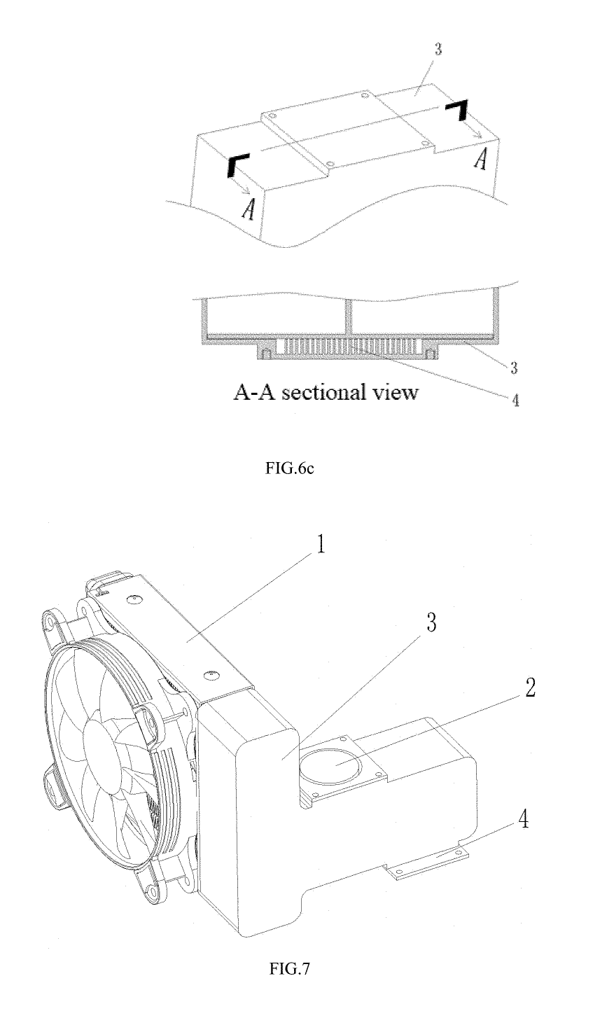

Referring to FIG. 6a, the outer periphery surface of the heat absorption device 4 is coated with welding flux, and the water reservoir 3 is coated with the welding flux, correspondingly. The heat absorption device 4 and the water reservoir 3 can be integratedly welded through the welding flux. Referring to FIG. 6b, the heat absorption device 4 may be fixed inside the water reservoir 3 by locking with screws or welding. Referring to FIG. 6c, the heat absorption device 4 is the original structure in the interior of the water reservoir 3, namely, the water reservoir 3 is internally provided with the heat absorption device beforehand, and the heat absorption device is integratedly formed with the water reservoir 3.

It should be noted that the technique of integratedly welding may be realized by directly welding two kinds of raw material with special equipment or welding with a third-party welding flux, such as solder paste, brazing flux, and weld-bonding metal. Special equipment can be used for welding the composite material, such as aluminum, aluminum alloy etc. The sealing device is an elastic gum seal ring, an elastic gum seal pad, or a glue-like filling and sealing material, etc.

Referring to FIG. 1, FIG. 2 and FIG. 5, the water reservoir 3 includes three space regions A, B and C. The dissipation device 1 is interconnected with region A. The pumping device 2 pumps the cooling liquid from region A to region B, the cooling liquid in the region B is transferred to region C through the heat absorption device 4. The region C and the region A are respectively connected to the water inflow channel and water outflow channel of the heat dissipation device 1.

The workflow of the liquid circulation is as follows. Referring to FIG. 5, the interior of the water reservoir 3 is partitioned into three working regions A, B, C. The region A is connected to the water outflow end of the heat dissipation device 1, and the upper side of the region A is provided with the hole-slot structure 31 for installing the pumping device 2. The region A is separated from region C, so as to separate the liquid before flowing into the heat dissipation device 1 with the liquid flowing out of the heat dissipation device 1. The region B is separated from the region C, so as to separate the liquid before heat absorption with the liquid after heat absorption. The cooling liquid flowing out from the upper half portion of the heat dissipation device 1 flows into region A through the water outlet \textcircled{1}, under the suction of the pumping device 2, then the cooling liquid flows to the water inlet \textcircled{3} of the pumping device 2 through the water channel \textcircled{2}. Under the pressure of the pumping device 2, the cooling liquid flows out from a water outlet \textcircled{4} to region B through the water channel \textcircled{5}, and then flows into a water inlet \textcircled{6} of the heat absorption device 4 from the region B. After the heat absorption, the cooling liquid enters region C from a water outlet \textcircled{7}, then returns back to the lower half portion of the heat dissipation device 1 from a water inlet \textcircled{8} to cool down, thereby getting ready for the next circulation of heat dissipation.

Referring to FIG. 7, the heat dissipation device 1 is welded on the side of the water reservoir, this arrangement can be applied in the case where the space in a length direction is limited. It is convenient for the arrangement of the heat dissipation device on a space of a flat square shape.

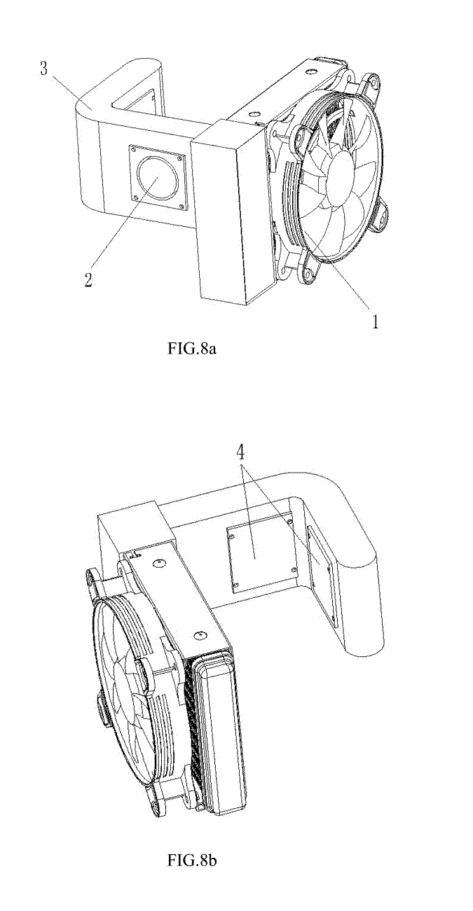

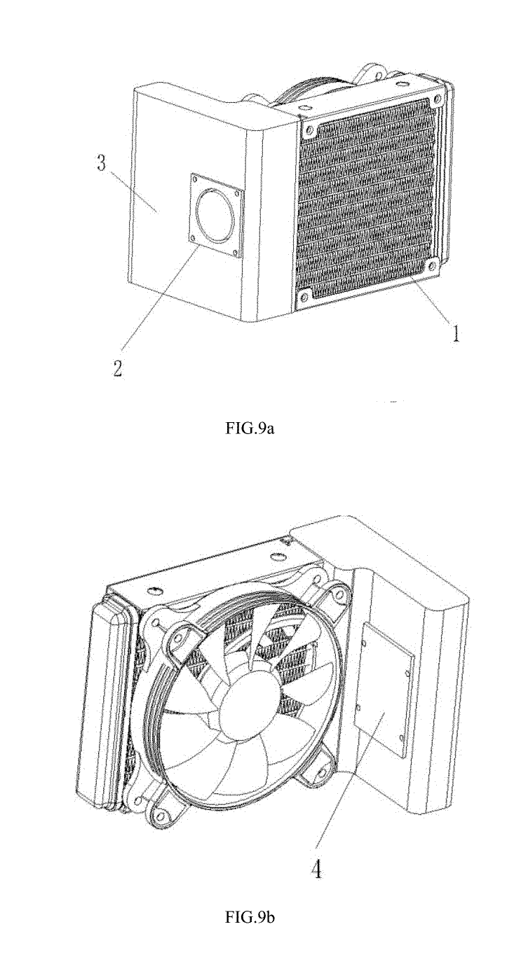

Referring to FIG. 8a, FIG. 8b and FIG. 9a, FIG. 9b, the pumping device 2 and the heat absorption device 4 may be arranged on the side of the water reservoir 3 so as to be suitable for different applications. For the heat-emitting bodies with different arrangements, the heat dissipation system of the present invention has more flexible designs.

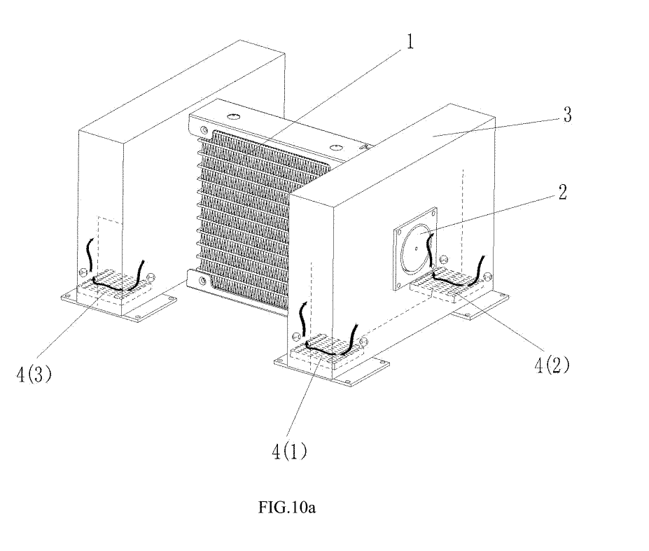

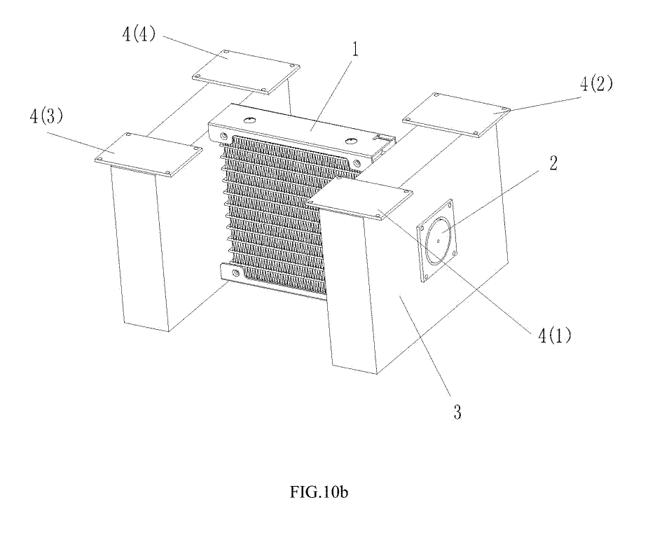

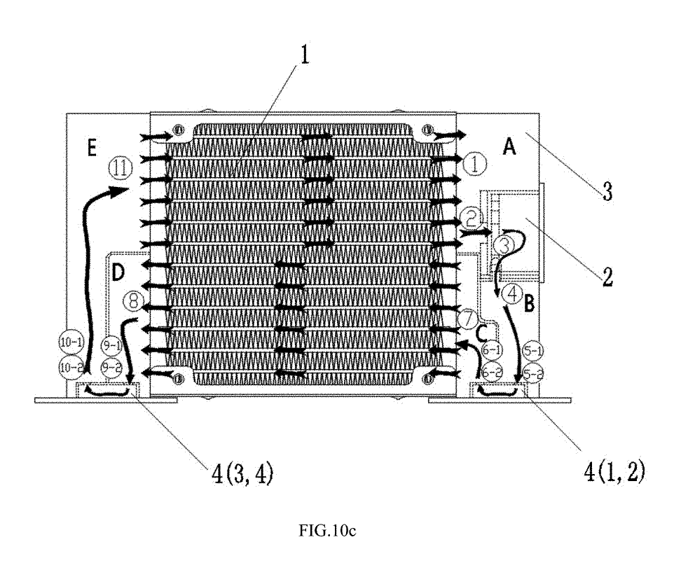

Referring to FIG. 10a and FIG. 10b, there are two water reservoirs disposed on both sides of the heat dissipation device 1, and the two water reservoirs are integratedly welded on the heat dissipation device 1. The bottom surface of the water reservoir on each side is provided with two absorption devices 4. A pumping device 2 is configured on the side of one of the water reservoirs. Referring to FIG. 10c, the specific circulation process of the liquid is as follows. The cooling liquid flowing out of the upper half portion of the heat dissipation device 1 enters region A from a water outlet \textcircled{1}, then flows into a water inlet \textcircled{3} of the pumping device 2 through the water channel \textcircled{2}. Under the pressure of the pumping device 2, the cooling liquid enters region B from a water outlet \textcircled{4}, and then enters water inlets [symbol] and [symbol] of the heat absorption devices 4(1) and 4(2) from the region B, in parallel or respectively. After heat absorption, the cooling liquid enters region C through water outlets [symbol] and [symbol] , then enters into the lower half portion of the heat dissipation device 1 through the water inlet \textcircled{7}. After cooling, the cooling liquid enters region D through the water channel \textcircled{8}, then enters water inlets [symbol] and [symbol] of the heat absorption devices 4(3) and 4(4), in parallel or respectively. After heat absorption, the cooling liquid enters region E through water outlets [symbol] and [symbol] , then returns back to the upper half portion of the heat dissipation device 1 through the water channel \textcircled{11}, thereby getting ready for the next circulation.

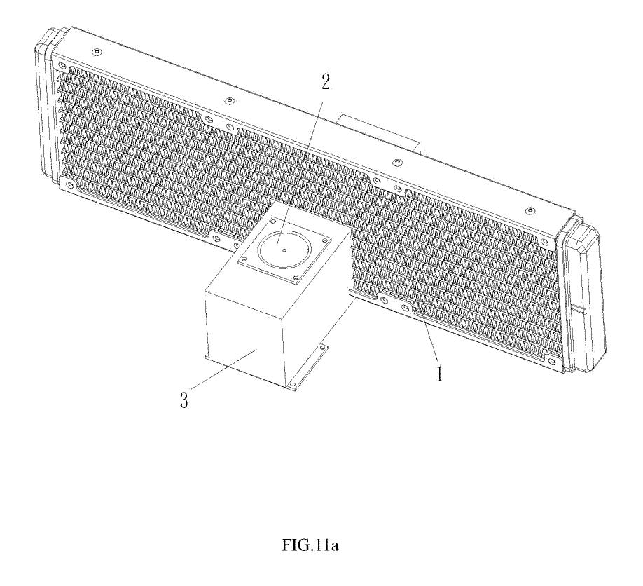

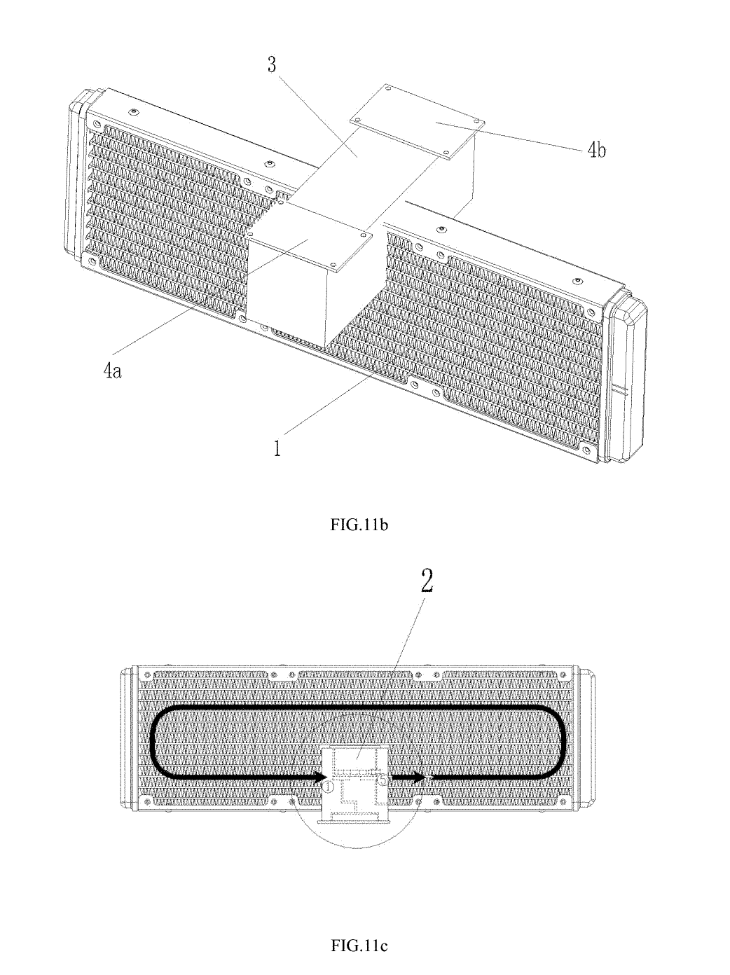

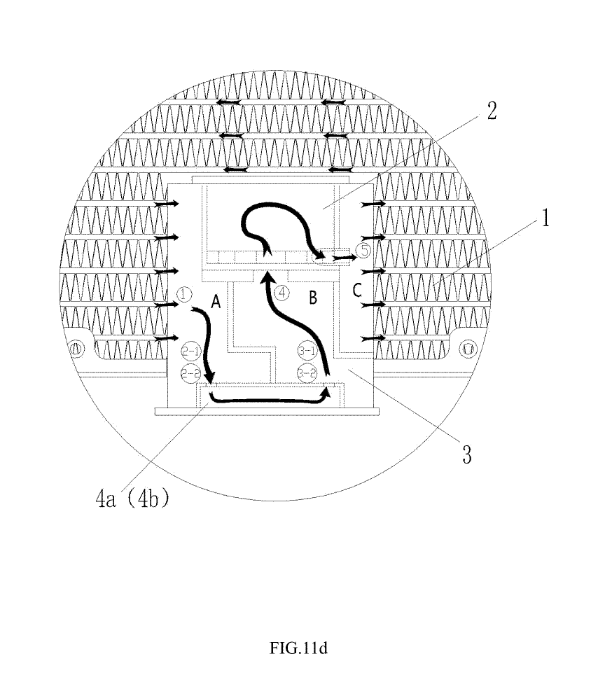

Referring to FIG. 11a and FIG. 11b, the water reservoir 3 and the heat dissipation device 1 are arranged in a cross-shaped manner. An absorption device 4 is configured on each side of the bottom of the water reservoir 3. The pumping device 2 is arrange on the top of a side of the water reservoir 3. Referring to FIG. 11c and FIG. 11d, the liquid circulation process of the liquid-cooling [symbol] is as follows [symbol] . The cooling liquid flowing out of a left side of the lower half portion of the heat dissipation device 1 enters region A of the water reservoir [symbol] through [symbol] the outlet \textcircled{1}, then flows into water inlets [symbol] and [symbol] of the heat absorption devices 4a and 4b, in parallel or respectively. After heat absorptions, the cooling liquid enters region B through water outlets [symbol] and [symbol] , then enters into the pumping device 2 through the water inlet Under the pressure of the pumping device 2, the cooling liquid flows out of the water outlet \textcircled{5} and enters region C, and then evenly enters a right side of the lower half portion of the heat dissipation device 1. The cooling liquid returns back to an outlet \textcircled{1} on the left side of the lower half portion of the heat dissipation device through the U-shaped loop in water chambers located on both sides of the heat dissipation device 1, thereby getting ready for the next heat dissipation circulation.

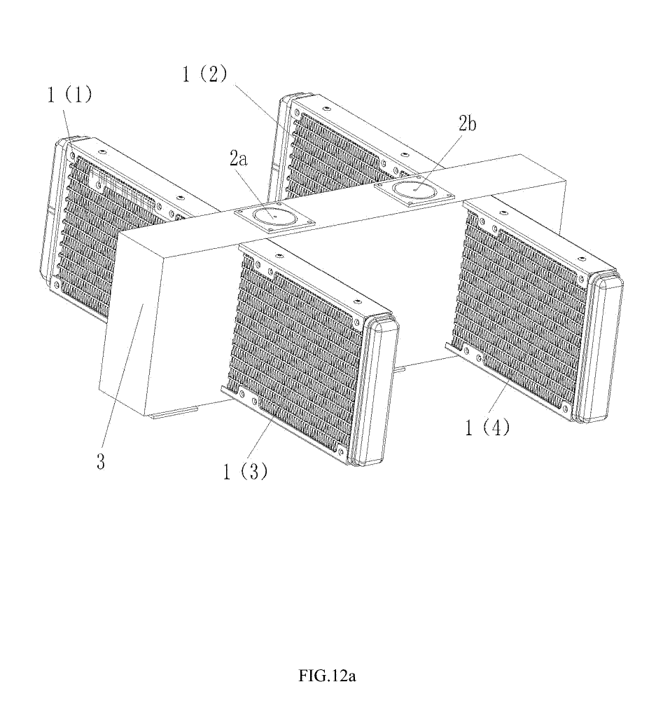

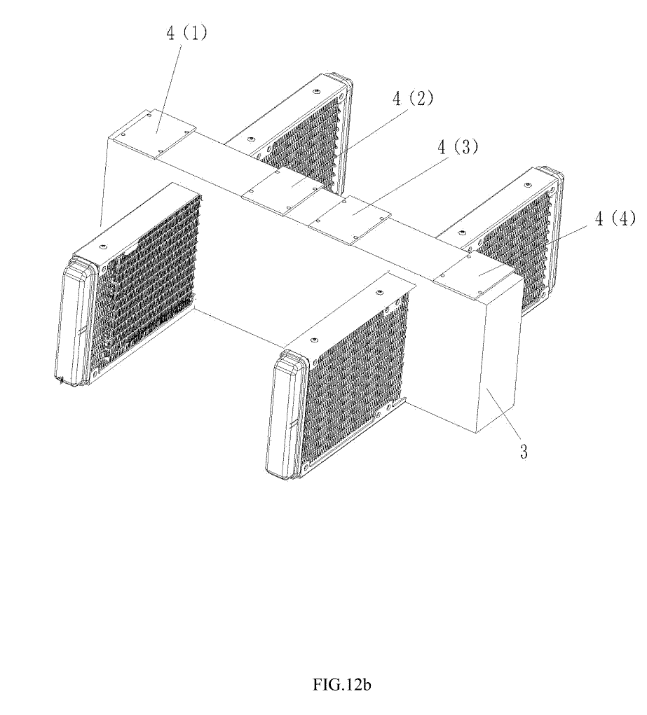

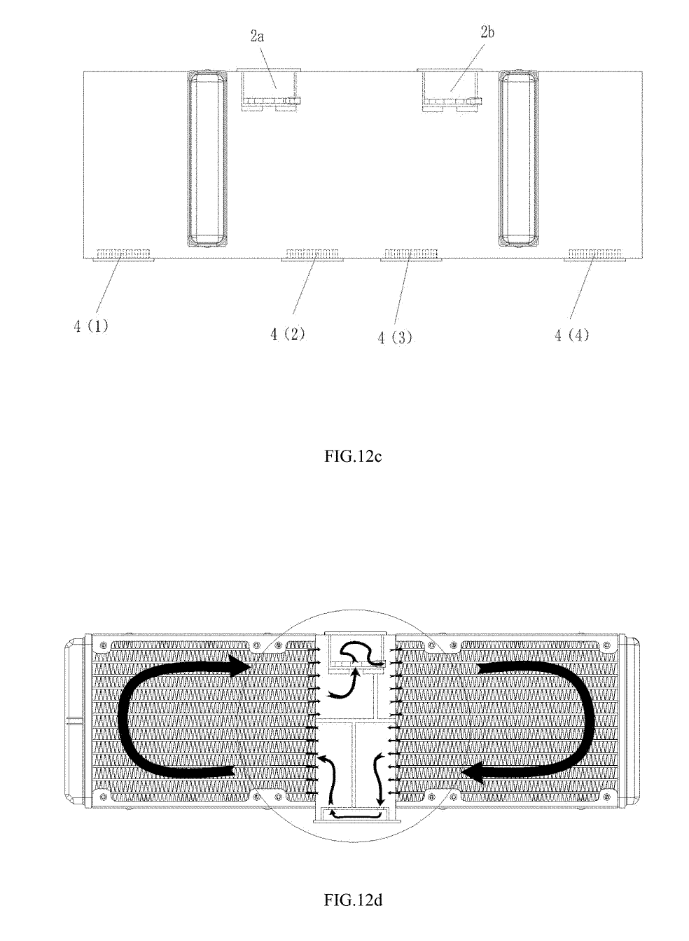

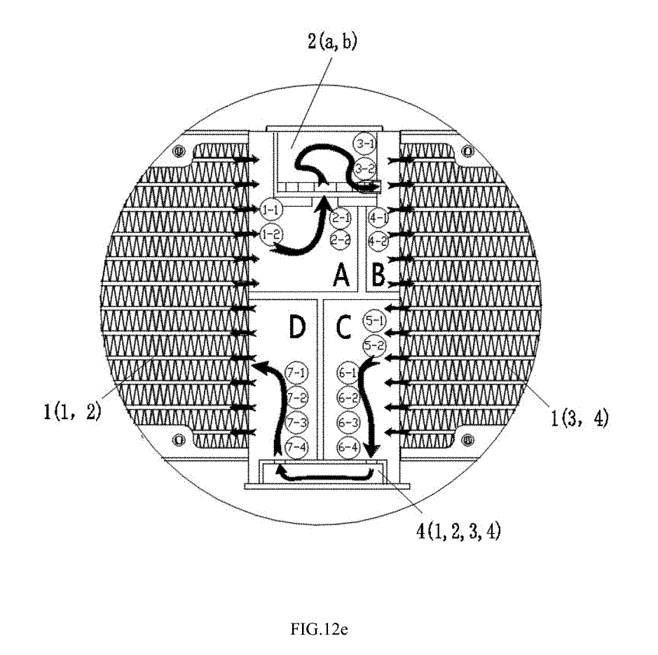

Referring to FIG. 12a to FIG. 12d two pumping devices 2a and 2b are configured on the top of the water reservoir 3, and the two pumping devices 2a, 2b are arranged between four heat dissipation devices 1(1), 1(2), 1(3) and 1(4). Four heat absorption devices 4(1), 4(2), 4(3) and 4(4) are configured on the opposite side of the water reservoir 3 corresponding to the pumping devices. Two heat absorption devices of the four are disposed among the four heat dissipation devices. Referring to FIG. 12e, the specific circulation process of the cooling liquid is as follows. The cooling liquid flowing out of the upper half portions of the heat dissipation devices 1(1), 1(2) enters region A through water outlets [symbol] , [symbol] , then evenly flows to the water inlets [symbol] , [symbol] of the pumping devices 2a and 2b. Under the pressure of the pumping device, the cooling liquid enters region B through water outlets [symbol] , [symbol] , and then evenly enters the upper half portions of the heat dissipation device 1(3), 1(4) in the region B. The cooling liquid returns back to the lower half portions of the heat dissipation device 1(3), 1(4) through the U-shaped flowing routes, and then flows and enters region C through water outlets [symbol] , [symbol] . After that, the flowing liquid evenly flows into the water inlets [symbol] , [symbol] , [symbol] and [symbol] of the heat absorption devices 4(1), 4(2), 4(3) and 4(4). After heat absorption, the cooling liquid enters region D through water outlets [symbol] , [symbol] , [symbol] and [symbol] then enters the lower half portions of the heat dissipation devices 1(1), 1(2). Then, the cooling liquid returns back to the upper half portions of the heat dissipation devices 1(1), 1(2) through the U-shaped flowing routes, thereby getting ready for the next circulation.

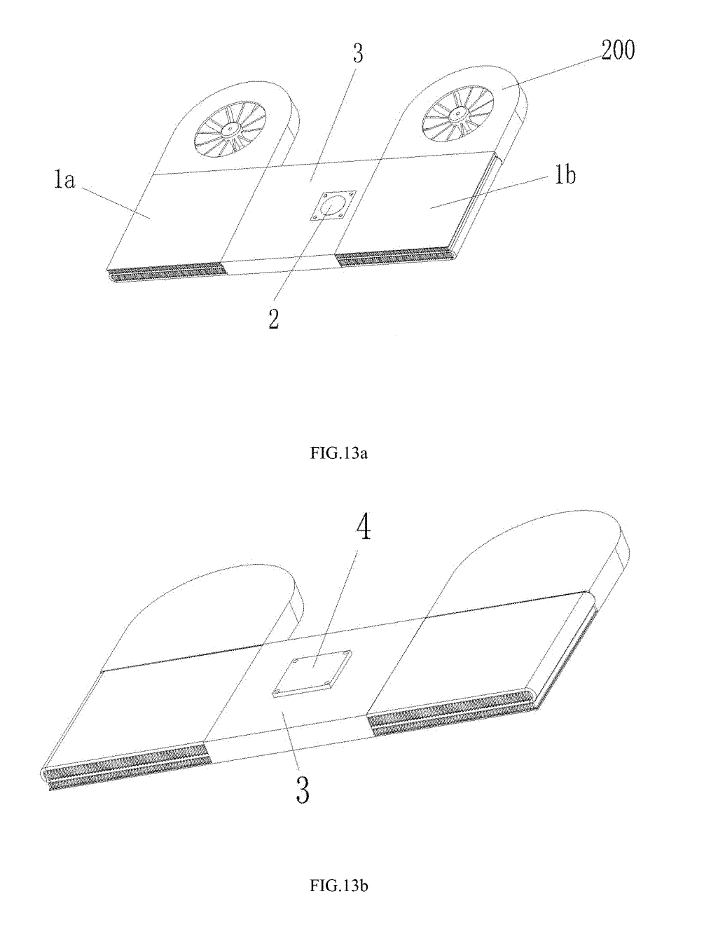

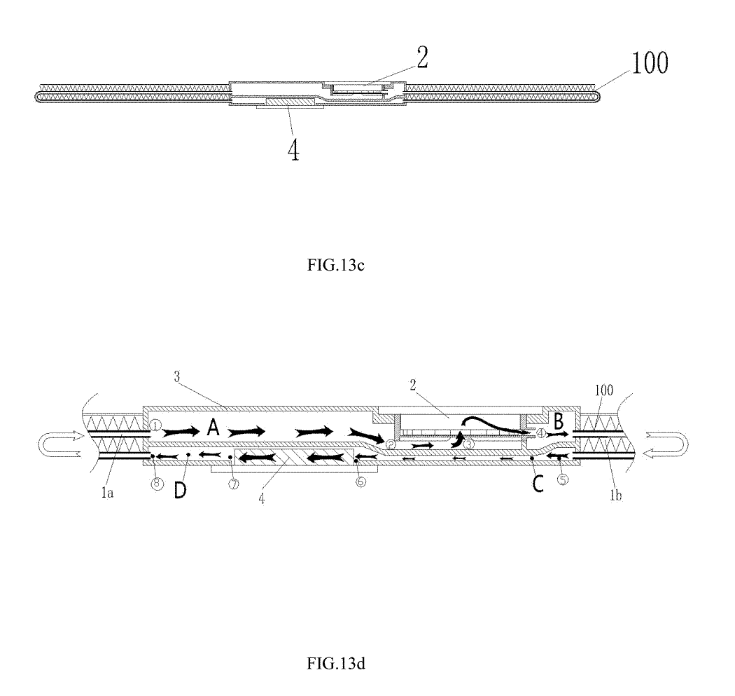

Referring to FIG. 13a to FIG. 13c, the ultra-thin liquid-cooled heat dissipation system includes a water reservoir 3 and the heat dissipation devices 1a and 1b welded on both ends of the water reservoir 3. Two sides of the water reservoir 3 are integratedlly welded with a pumping device 2 and a heat absorption device 4, respectively. The heat dissipation in heat dissipation device 1a is mainly performed by using a flat U-shaped pipe 100, and turbo fans 200 are configured on the side of the heat dissipation device la for cooling the U-shaped pipe 100. Accordingly, the heat dissipation device can have a thinner shape. Referring to FIG. 13d, the specific circulation process of the cooling liquid is as follows. The cooling liquid flowing out of the upper half portion of the heat dissipation device 1a enters region A from the water outlet \textcircled{1}, then flows to a water inlet \textcircled{3} of the pumping device 2 through the water channel \textcircled{2}. Under the pressure of the pumping device 2, the cooling liquid flows out of the water outlet \textcircled{4} and enters region B, and then flows into the upper half portion of the heat dissipation device 1b from the region B. After that, the cooling liquid flows into the lower half portion of the heat dissipation device 1b through the U-shaped flowing route, then enters region C through the water outlet \textcircled{5}. Then, the cooling liquid passes through the water inlet \textcircled{6} of the heat absorption device 4. After heat absorption, the cooling liquid flows out of a water outlet \textcircled{7} and enters region D, then returns back to the lower half portion of the heat dissipation device 1a through the water inlet \textcircled{8}, and then returns back to the upper half portion of the heat dissipation device 1a through the U-shaped flowing route, thereby getting ready for the next circulation.

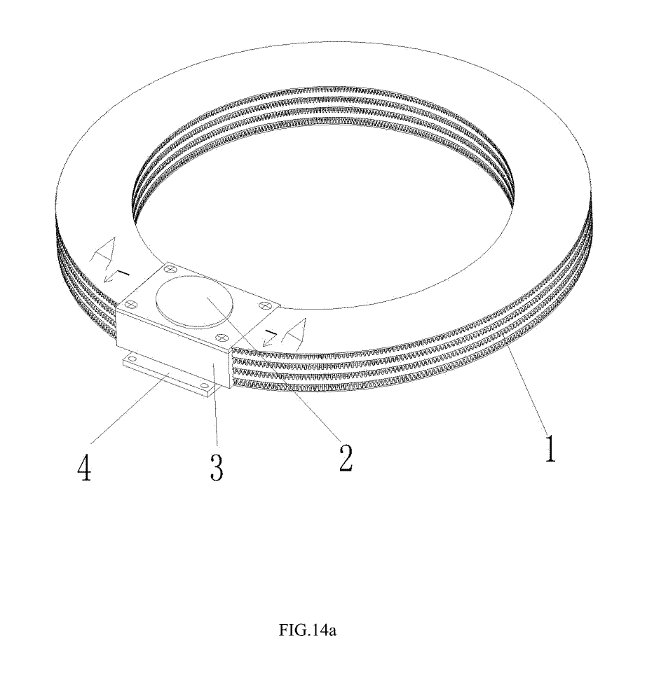

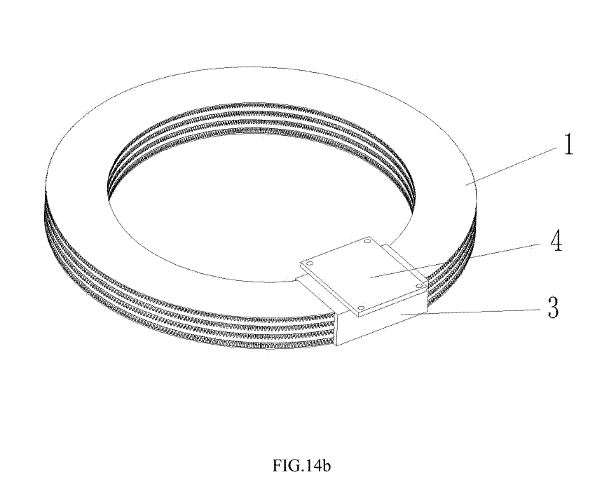

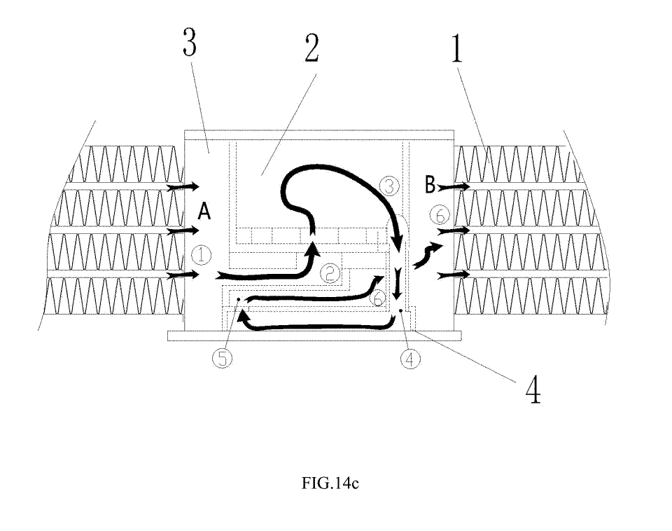

Referring to FIG. 14a to FIG. 14c, the interior of the water reservoir 3 is partitioned into two space regions A, B, and the two space regions are a water inflow region and a water outflow region of the heat dissipation device 1, respectively. The pumping device 2 directly pumps the cooling liquid from the space region A to the water inlet of the heat absorption device 4, and then connected to the space region B through the water outlet of the heat absorption device 4. Specifically, referring to FIG. 14c, the cooling liquid flowing out of the left side of the heat dissipation device 1 enters region A through the water outlet \textcircled{1}, and then enters a water inlet \textcircled{2} of the pumping device 2. Under the pressure of the pumping device 2, the cooling liquid enters into the water inlet \textcircled{4} of the heat absorption device 4 from the water outlet \textcircled{3}. After heat absorption, the cooling liquid enters region B from the water outlet \textcircled{5} though a water channel \textcircled{6}, then flows into the right side of the heat dissipation device 1 and returns back to the left side of the heat dissipation device through the circular loop of the heat dissipation device, thereby getting ready for the next circulation. Certainly, the interior of the water reservoir may be partitioned to several space regions for controlling the circulation and flowing direction of the liquid, such as three regions, four regions, etc.

It can be learned from the above listed embodiments that the water reservoir of the present invention may be provided and interconnected with N pumping devices, N≥2, N heat absorption devices, N≥2, and N heat dissipation devices, N≥2, and the specific arrangements of these components are multitudinous.

The above descriptions merely involve the preferred embodiments of the present invention. Various changes or equivalent substitutions to these features and embodiments can be derived by those skilled in the art without departing from the spirit and scope of the invention. In addition, with the teachings of the present invention, these features and embodiments may be modified to adapt to the specific circumstances and materials without departing from the spirit and scope of the invention. Therefore, the present invention is not limited to the specific embodiments disclosed herein, and all the embodiments falling within the scope of the claims of the present application should be considered as falling within the scope of the present invention.

What is claimed is:

1. A pipeless liquid-cooled heat dissipation system, comprising:
a heat dissipation device, a pumping device, a water reservoir, and a heat absorption device;
wherein,
the pumping device, the heat absorption device, the heat dissipation device, and the water reservoir are integrated and interconnected without a pipe; an interior of the water reservoir is partitioned into at least two space regions to control a flow direction of a cooling liquid;
a hole-slot structure is arranged on the water reservoir, and the pumping device is installed in the hole-slot structure and interconnected with the water reservoir;
the heat absorption device is further integratedly configured on the water reservoir and interconnected with the water reservoir; and
the water reservoir and the heat dissipation device are integratedly formed by welding and are interconnected with each other.

2. The pipeless liquid-cooled heat dissipation system according to claim 1, wherein
a manner of an integrated formation of the water reservoir and the heat dissipation device by welding comprises directly welding the water reservoir and the heat dissipation device by special equipment after butting interfaces of a raw material of the water reservoir and a raw material of the heat dissipation device, or welding the water reservoir and the heat dissipation device through a third-party welding flux.

3. The pipeless liquid-cooled heat dissipation system according to claim 1, wherein
the water reservoir comprises two space regions A and B, and the two space regions A, B are connected by the heat dissipation device;
the heat absorption device comprises a water inflow region and a water outflow region;
the pumping device directly pumps the cooling liquid from the space region A to the water inflow region of the heat absorption device; and
the cooling liquid is transferred to the space region B through the water outflow region of the heat absorption device.

4. The pipeless liquid-cooled heat dissipation system according to claim 1, wherein
the water reservoir comprises three space regions A, B and C;
the dissipation device is interconnected with the space region A;
the pumping device pumps the cooling liquid from the space region A to the space region B; the cooling liquid in the space region B is transferred to the space region C through the heat absorption device; the space region A and the space region C are connected to the water inflow channel and a water outflow channel of the heat dissipation device, respectively.

5. The pipeless liquid-cooled heat dissipation system according to claim 1, wherein
the heat dissipation device is configured at two sides of the water reservoir, respectively;
the water reservoir is partitioned into four space regions A, B, C and D;
the pumping device pumps the cooling liquid to the space region B from the space region A; the space region A and the space region D, and the space region B and the space region C are respectively connected by two of the heat dissipation devices; and
the cooling liquid in the space region C is transferred to the space region D through the heat absorption device.

6. The pipeless liquid-cooled heat dissipation system according to claim 5, wherein
the water reservoir has a thin flat shape, the heat dissipation device is flat large U-shaped pipelines, and the heat dissipation device is provided with a turbo fan.

7. The pipeless liquid-cooled heat dissipation system according to claim 1, wherein
the pumping device comprises a pump housing, an impeller, a motor, and a pump cover component, and the pumping device is locked and sealed with the water reservoir through a sealing device.

8. The pipeless liquid-cooled heat dissipation system according to claim 1, wherein
the heat absorption device is a metal piece with high heat conductivity, the heat absorption device is locked and sealed with the water reservoir through a sealing device or integratedly welded;
the interior of the water reservoir is provided with the heat absorption device; or the original internal structure of the water reservoir forms the heat absorption device.

9. The pipeless liquid-cooled heat dissipation system according to claim 7, wherein
the sealing device is an elastic gum seal ring, an elastic gum seal pad, or a glue-like filling and sealing material.

10. The pipeless liquid-cooled heat dissipation system according to claim 9, wherein
the water reservoir is provided and interconnected with N pumping devices, N≥2, N heat absorption devices, N≥2, and N heat dissipation devices, N≥2.

11. The pipeless liquid-cooled heat dissipation system according to claim 2, wherein
the water reservoir comprises three space regions A, B and C;
the dissipation device is interconnected with the space region A;
the pumping device pumps the cooling liquid from the space region A to the space region B; the cooling liquid in the space region B is transferred to the space region C through the heat absorption device; the space region A and the space region C are connected to the water inflow channel and a water outflow channel of the heat dissipation device, respectively.

12. The pipeless liquid-cooled heat dissipation system according to claim 2, wherein
the heat dissipation device is configured at two sides of the water reservoir, respectively;
the water reservoir is partitioned into four space regions A, B, C and D;
the pumping device pumps the cooling liquid to the space region B from the space region A; the space region A and the space region D, and the space region B and the space region C are respectively connected by two of the heat dissipation devices; and
the cooling liquid in the space region C is transferred to the space region D through the heat absorption device.

13. The pipeless liquid-cooled heat dissipation system according to claim 12, wherein the water reservoir has a thin flat shape, the heat dissipation device is flat large U-shaped pipelines, and the heat dissipation device is provided with a turbo fan.

14. The pipeless liquid-cooled heat dissipation system according to claim 8, wherein the sealing device is an elastic gum seal ring, an elastic gum seal pad, or a glue-like filling and sealing material.

15. The pipeless liquid-cooled heat dissipation system according to claim 14, wherein the water reservoir is provided and interconnected with N pumping devices, N≥2, N heat absorption devices, N≥2, and N heat dissipation devices, N≥2.
